(19) United States
(12) Patent Application Publication
(10) Pub. No.: US 2005/0000730 A1
(43) Pub. Date: Jan. 6, 2005

(54) Printed wiring board, electronic component mounting method, and electronic apparatus

(75) Inventor: Akihiko Happoya, Fussa-shi (JP)

Correspondence Address: Finnegan, Henderson, Farabow,;Garrett & Dunner, L.L.P., 1300 I Street, N.W., Washington, DC, 20005-3315, US

(73) Assignee: KABUSHIKI KAISHA TOSHIBA

(21) Appl. No.: 10/874,305

(22) Filed: Jun. 24, 2004

(30) Foreign Application Priority Data
Jul. 2, 2003 (JP) 2003-190338

(51) Int. Cl. H05K 1/16; H05K 1/11

(52) U.S. Cl. 174/262; 29/832; 174/260

(57) ABSTRACT

A printed wiring board comprises a pad on which a surface mounting component is mounted, and a through hole into which a lead wire of an electronic component provided with the lead wire is inserted, and a surface treatment is performed to apply nickel-gold plating to the through hole to coat the pad with a water-soluble preflux.

### CROSS-REFERENCE TO RELATED APPLICATIONS

This application is based upon and claims the benefit of priority from prior Japanese Patent Application No. 2003-190338, filed Jul. 2, 2003, the entire contents of which are incorporated herein by reference.

### BACKGROUND OF THE INVENTION

1. Field of the Invention

The present invention relates to a printed wiring board in which surface mounting components, and electronic components provided with lead wires, using through holes, are mounting targets, an electronic component mounting method, and an electronic apparatus.

2. Description of the Related Art

Various improvements and enhancements have been intended constantly in consideration of cost performance in each working process in a multilayered printed wiring board (see Jpn. Pat. Appln. KOKAI Publication No. 7-273453, for example).

In the printed wiring board, solder does not reach an upper part of a through hole (the hole is not sufficiently filled) in a process in a lead wire of an electronic component provided with the lead wire is inserted in the through hole, and soldered.

When the printed wiring board is formed in a product while keeping this soldered/mounted state, the product is remarkably vulnerable to vibration, external stress and the like. Especially in electronic apparatuses such as a personal computer, various connector components to which an external stress is added need to be mounted as electronic components provided with the lead wires on a circuit substrate. When soldered portions of component mounted portions are cracked, needless to say, troubles are caused in an operation and a function of the electronic apparatus on which, for example, a printing unit is mounted, and many problems are caused in various aspects such as durability and reliability.

A defect that the solder for bonding the component lead wire to the through hole does not reach the upper part of the through hole, that is, a soldering defect is subjected to a correction process using flow soldering or a soldering iron so that the solder is extended (filled) to the upper part of the through hole from a lower side of the soldered portion.

A phenomenon in which the solder does not rise to the upper part of the through hole tends to be frequently seen, especially when solder wettability in the through hole drops by the surface mounting of two front and back surfaces, when a board thickness of the printed wiring board is large, or when a solder material is specified. When the surface mounting is performed twice on the front and back surfaces, a surface treatment is degraded, and solder wettability in the through hole drops. Therefore, even when the electronic component provided with the lead wire is inserted into the through hole and soldered after the surface mounting, the solder does not rise to the upper part of the through hole. As compared with a tin-lead based eutectic solder which has heretofore been general, a tin-silver-copper based lead-free solder tends not to rise to the upper part of the through hole. It is to be noted that the use of the tin-lead based eutectic solder is severely restricted in an environmental aspect, and therefore use of the lead-free solder in which lead in the solder used in the soldering is eliminated has been promoted. Therefore, even when the lead wire of the electronic component provided with the lead wire is inserted into the through hole of the printed wiring board, and soldered with the lead-free solder, the cell needs to be sufficient raised to the upper part of the through hole.

As described above, there has not heretofore been any effective means for removing a disadvantage that the solder is not raised to the upper part of the through hole (not sufficiently filled) in a soldering process in which the electronic component provided with the lead wire is inserted in the through hole.

### BRIEF SUMMARY OF THE INVENTION

In the through hole into which the lead wire of the electronic component provided with the lead wire is inserted and soldered, it is preferable to use a surface treatment having good solder wettability so that the surface treatment in the through hole is not deteriorated by heat history as much as possible in a surface mounting treatment.

A printed wiring board according to a first aspect of the present invention characterized by comprising: a pad on which a surface mounting component is mounted; and a through hole into which a lead wire of an electronic component provided with the lead wire is inserted, and a surface treatment is performed to apply nickel-gold plating to the through hole to coat the pad with a water-soluble preflux.

An electronic component mounting method according to a second aspect of the present invention is characterized by comprising: plating a through hole disposed in a lead component mounting portion on which an electronic component provided with a lead wire is to be mounted with nickel-gold and coating a pad disposed on a surface mounting portion on which a surface mounting component is to be mounted with a water-soluble preflux to subject a printed wiring board to a surface treatment; mounting the surface mounting component on the surface mounting portion of the printed wiring board; and inserting the lead wire of the electronic component provided with the lead wire into the through hole of the printed wiring board to mount the electronic component provided with the lead wire on the lead component mounting portion after the reflow, and the surface mounting component and the electronic component provided with the lead wire are mounted on the printed wiring board.

An electronic apparatus according to a third aspect of the present invention characterized by comprising: a substrate comprising a through hole into which a lead wire of an electronic component disposed on a mounting portion of the electronic component to which an external stress is applied is to be inserted and soldered and which is plated with nickel-gold; and an electronic component whose lead wire is inserted and soldered in the through hole disposed in the substrate and which is mounted on the substrate.

### BRIEF DESCRIPTION OF THE SEVERAL VIEWS OF THE DRAWING

FIG. 1 is a sectional view showing a surface treatment state of a printed wiring board in a first embodiment of the present invention;

FIG. 2 is a diagram showing a surface treatment process in the first embodiment;

FIG. 3 is a diagram showing characteristics of a surface treatment in each embodiment in comparison;

FIG. 4 is a plan view showing a concrete arrangement example of a lead component mounting portion of the printed wiring board in the first embodiment;

FIGS. 5A to 5K are diagrams showing a component mounting step in the first embodiment;

FIG. 6 is a diagram showing a solder rising state of a through hole portion in the first embodiment;

FIG. 7 is a diagram showing the solder rising state of the through hole portion which is not subjected to the surface treatment in the first embodiment, in contrast to FIG. 6;

FIG. 8 is a perspective view showing a mounting example of an electronic component provided with a lead wire, which is an object of the surface treatment in the first embodiment; and

FIG. 9 is a diagram showing the surface treatment process in a second embodiment of the present invention.

### DETAILED DESCRIPTION OF THE INVENTION

Embodiments of the present invention will be described with reference to the drawings.

FIG. 1 is a diagram showing a surface treatment state of a printed wiring board in a first embodiment of the present invention. A component mounting portion of the surface of a printed wiring board 10 is provided with through holes 11 and through hole lands 12 in which lead wires 21 of an electronic component 20 provided with the lead wires are to be inserted, and pads (foot prints) 13 on which a surface mounting component 30 is to be mounted.

In the printed wiring board 10 including the through holes 11 into which the lead wires 21 of the electronic component 20 provided with the lead wires are inserted and the pads (foot prints) 13 onto which the surface mounting component 30 is mounted, a surface treatment is performed so as to perform quick and satisfactory soldering in reflow and flow treatments for soldering the surface mounting component 30 and the electronic component 20 provided with the lead wires. In this case, it is preferable to use a surface treatment having good solder wettability, so that the surface treatment in the through holes 11 is not easily deteriorated as much as possible by heat history by a surface mounting process.

Here, the through holes 11 in which the lead wires 21 are inserted and the through hole lands 12, disposed in the mounting portion (lead component mounting portion) of the electronic component 20 provided with the lead wires, are subjected to the surface treatment by nickel-gold plating (PL), and each pad 13 disposed on the mounting portion (surface mounting portion) of the surface mounting component 30 is subjected to the surface treatment by a water-soluble preflux (Pf).

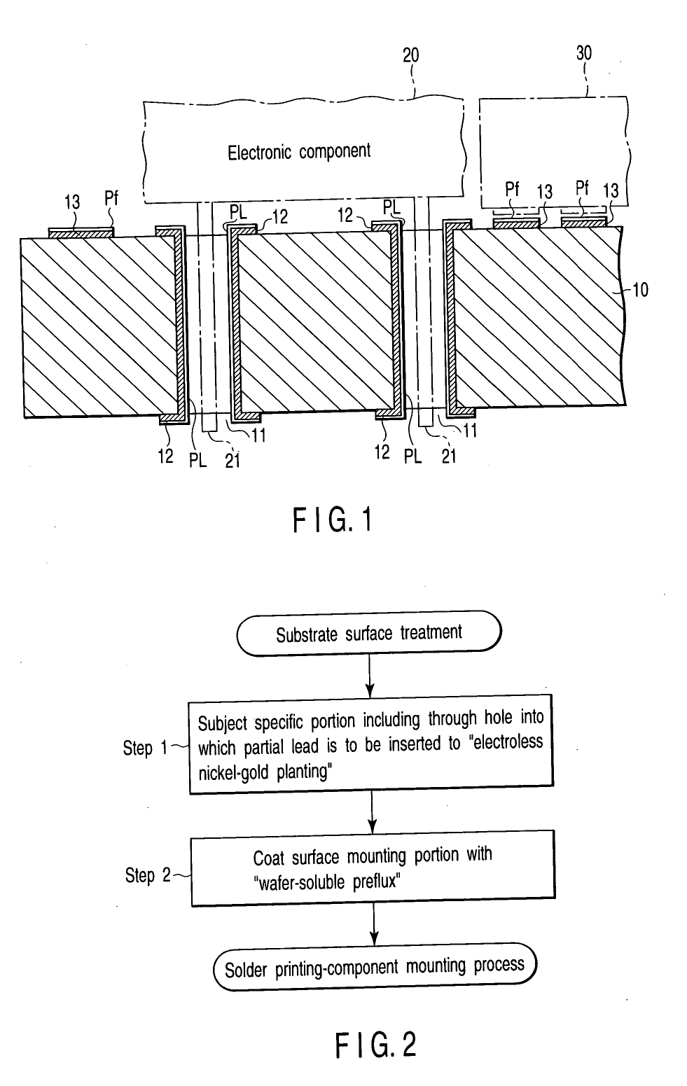

A surface treatment process in this case is shown in FIG. 2. In the first embodiment, the surface treatment by the nickel-gold plating (PL) is performed onto each through hole 11 and through hole land 12 of the lead component mounting portion using electroless nickel-gold plating means which does not require any electrode for the plating (lead-out wire for the plating).

In the surface treatment process shown in FIG. 2, the printed wiring board 10 including the through holes 11 and through hole lands 12 disposed in the lead component mounting portion and the pads 13 disposed on the surface mounting portion is used as a surface treatment target. First in step 1, the lead component mounting portion of the printed wiring board 10 in which the through holes 11 and through hole lands 12 are disposed is subjected to the surface treatment by the nickel-gold plating (PL) using the electroless nickel-gold plating means.

Next, in step 2, the surface mounting portion on which the pads 13 are disposed is subjected to the surface treatment by the water-soluble preflux (Pf).

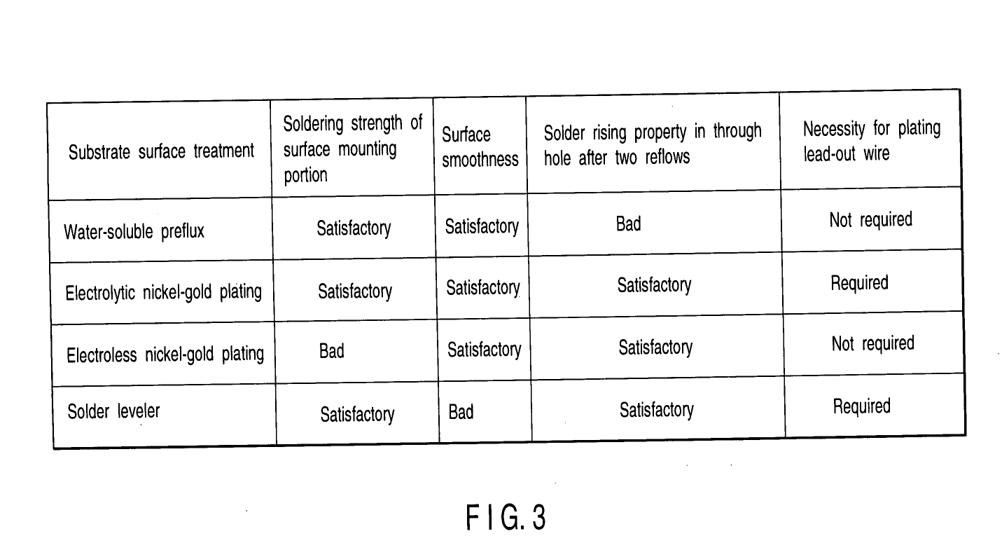

Characteristics of a representative surface treatment of the printed wiring board including the through holes disposed in the lead component mounting portion and the pads disposed on the surface mounting portion, which is an object of the present invention, are shown in FIG. 3.

As shown in FIG. 3, the surface treatment by the water-soluble preflux has characteristics that “soldering strength of the surface mounting component” and “surface smoothness” are both satisfactory, but “solder rising property in through hole after two reflows on front and back surfaces” is bad. In the surface treatment by the electrolytic nickel-gold plating, the “soldering strength of the surface mounting component”, “surface smoothness”, and “solder rising property in the through hole after two reflows on the front and back surfaces” are satisfactory, but there is a disadvantage that an electrode for the plating (lead-out wire for the plating) has to be disposed. In the surface treatment by the electroless nickel-gold plating, the surface treatment by the water-soluble preflux has characteristics that the “surface smoothness” are “solder rising property in the through hole after two reflows on the front and back surfaces” are both satisfactory, but the “soldering strength of the surface mounting component” is inferior. In the surface treatment by a solder leveler, the “soldering strength of the surface mounting component” and “solder rising property in the through hole after two reflows on the front and back surfaces” are satisfactory, but the “surface smoothness” is bad.

In consideration of the characteristics of the surface treatments, in the first embodiment of the present invention, as described above, the surface treatment by the nickel-gold plating (PL) is performed onto each through hole 11 and through hole land 12 of the lead component mounting portion using the lead-free nickel-gold plating means which does not require any electrode for the plating (lead-out wire for the plating).

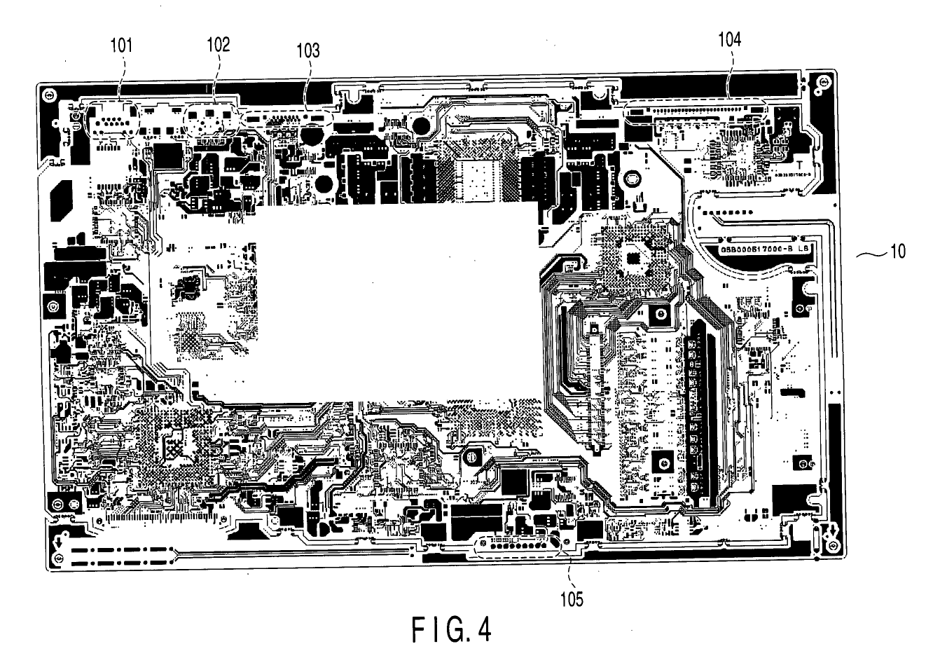

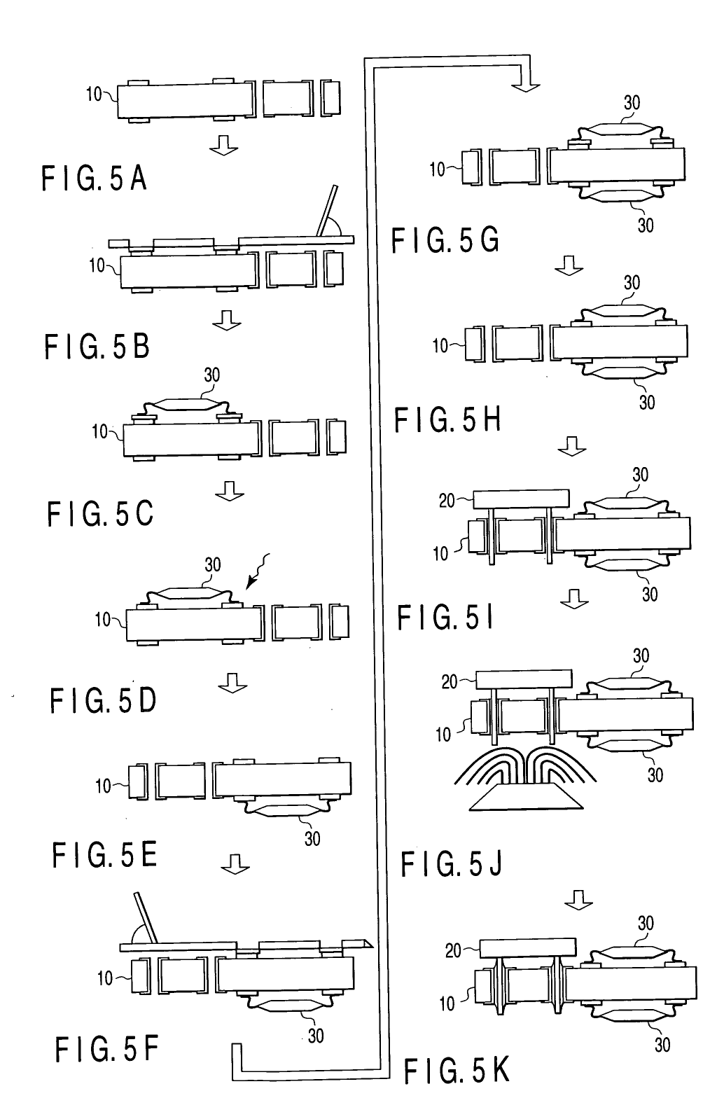

A concrete example of the component mounting process of the printed wiring board 10 subjected to the surface treatment by the first embodiment is shown in FIGS. 4 and 5A to 5K.

In the printed wiring board 10, as shown in FIG. 4, lead component mounting portions 101 to 105 are disposed for mounting a plurality of electronic components provided with the lead wires, such as connector components, mainly on a peripheral portion of a substrate. Each of the lead component mounting portions 101 to 105 is, as shown in FIG. 1, provided with the through holes 11 into which the lead wires 21 of the electronic component 20 provided with the lead wires are inserted and soldered, and the through hole lands 12. On a surface mounting portion excluding the lead component mounting portions 101 to 105, as shown in FIG. 1, the pads 13 on which the surface mounting component 30 is to be soldered and mounted is disposed.

On the printed wiring board 10 in which the electronic components provided with the lead wires are arranged as shown in FIG. 4, as shown in FIGS. 5A to 5K, the reflow treatment is performed twice on the front and back surfaces of the printed wiring board 10 to mount the surface mounting component 30 by the soldering. Further on the lead component mounting portions 101 to 105 of the printed wiring board 10, the lead wires 21 of the electronic component 20 provided with the lead wires are inserted into the through holes 11 to solder/mount the component.

In a first reflow process shown in FIGS. 5A to 5D, the surface mounting component 30 is mounted and soldered onto one surface (e.g., the front surface) of the printed wiring board 10. Subsequently, in a second reflow process shown in FIGS. 5E to 5H, the surface mounting component 30 is mounted on the other surface (e.g., the back surface) of the printed wiring board 10. Furthermore, in a flow process shown in FIGS. 5I to 5K, the electronic component 20 provided with the lead wires is mounted, for example, on the front surface of the printed wiring board 10, and soldered by jet soldering of a flow device, for example, from the back surface.

In the first reflow process shown in FIGS. 5A to 5D, in the step shown in FIG. 5A, the printed wiring board 10 is projected as a printed wiring board on which components are to be mounted into a reflow line. In the step shown in FIG. 5B, a cream solder is printed (coated) on the surface mounting portion, for example, of the front surface of the printed wiring board 10 projected in the reflow line using a squeeze, metal mask or the like. In the step shown in FIG. 5C, the surface mounting component 30 is mounted on the surface mounting portion on which the cream solder is printed. In the step shown in FIG. 5D, the surface mounting component 30 mounted on the surface mounting portion is soldered by the reflow device. Exactly, each electrode (pad) of the surface mounting component 30 is bonded to the pad 13 by solder melting, and accordingly the surface mounting component 30 is soldered/mounted onto the surface mounting portion of the printed wiring board 10.

Subsequently, in the second reflow process shown in FIGS. 5E to 5H, in the step shown in FIG. 5E, the surface-treated printed wiring board 10 is reversed. In the step shown in FIG. 5F, the cream solder is printed on the surface mounting portion of the back surface of the printed wiring board 10 using the squeeze, metal mask or the like. In the step shown in FIG. 5G, the surface mounting component 30 is mounted on the surface mounting portion on which the cream solder is printed. In the step shown in FIG. 5H, the surface mounting component 30 mounted on the surface mounting portion is soldered by the reflow device.

Subsequently, in the flow process shown in FIGS. 5E to 5K, in the step shown in FIG. 5E, the lead wires 21 of the electronic component 20 provided with the lead wires are inserted in the through holes 11 of the lead component mounting portions 101 to 105 to mount the electronic component 20 provided with the lead wires on the lead component mounting portions 101 to 105. In the step shown in FIG. 5J, the electronic component 20 provided with the lead wires is soldered by a solder jet from the back surface in the flow device. In the step shown in FIG. 5K, the printed wiring board 10 on which the electronic component 20 provided with the lead wires and the surface mounting components 30 are mounted is fed as a printed circuit board (circuit substrate) to the next step.

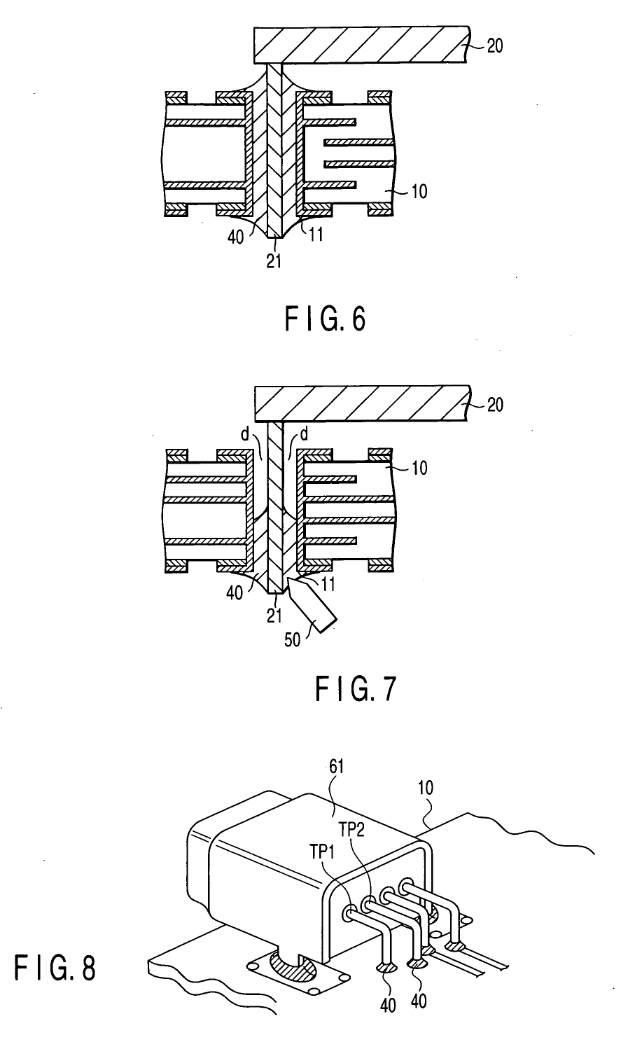

In this manner, the through holes 11 and through hole lands 12 of the lead component mounting portion of the printed wiring board 10 are subjected to the surface treatment by the nickel-gold plating (PL), each pad 13 of the surface mounting portion is subjected to the surface treatment by the water-soluble preflux (Pf), and the reflow is performed twice on the front and back surfaces of the printed wiring board 10. A solder rising state in the through holes 11 after the process is shown in FIGS. 6 and 7 in contrast with the solder rising state in a case where the surface treatment of the through hole-11 is not performed.

FIG. 6 shows a solder rising state when the surface treatment is performed at each through hole 11 and through hole land of the lead component mounting portion with the nickel-gold plating (PL). FIG. 7 shows a solder rising state when the surface treatment is not performed at each through hole 11 and through hole land of the lead component mounting portion with the nickel-gold plating (PL). in FIG. 7, a gap portion by shortage of the solder is shown by the reference symbol d.

In the solder rising state shown in FIG. 6, a solder 40 is sufficiently turned (filled) in the through hole 11, and each lead wire 21 of the electronic component 20 provided with the lead wire is firmly bonded/fixed by the solder 40 by satisfactory solder rising. Therefore, when the circuit substrate is mounted on the apparatus, the circuit is capable of sufficiently bearing any vibration, shock or the like, a stable circuit operation can be maintained over a long period, and this highly reliable electronic apparatus can be provided. In the solder rising state shown in FIG. 7, the solder 40 is not sufficiently turned (filled) in the through hole 11, a gap portion (d) by shortage of the solder is generated in the through hole 11, and a structure is vulnerable to external stress, vibration, or the like. Especially in small-sized electronic apparatuses such as a personal computer, PDA, and portable computer, as shown in FIG. 8, a connector component in which the external stress is added to a peripheral portion of the substrate or the like is mounted in many cases. When the embodiment of the present invention is applied to the component mounting portion, a highly reliable device capable of sufficiently bearing the external stresses such as the vibration and impact can be provided. It is to be noted that FIG. 8 shows a mounting example of an IEEE 1394 connector 61 comprising a plurality of lead wires (TP1, TP2, . . . ) as an object electronic component.

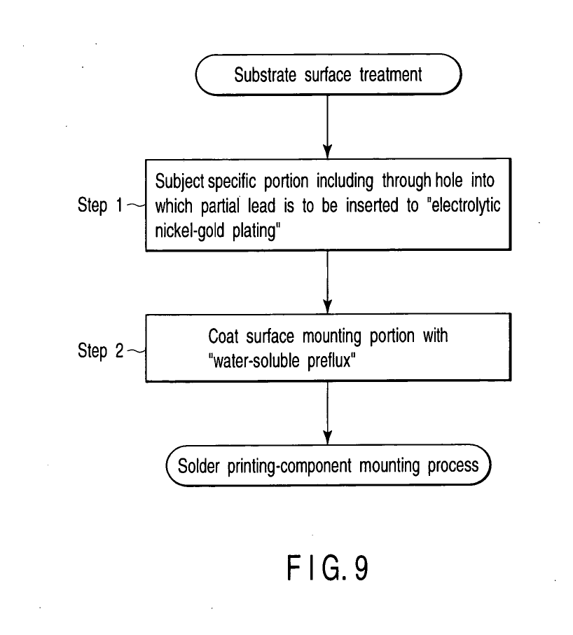

In the first embodiment, an example in which each through hole 11 of the lead component mounting portions 101 to 105 is subjected to the surface treatment by the electroless nickel-gold plating. However, for example, instead of the surface treatment process shown in FIG. 2, the surface treatment process by electrolytic nickel-gold plating means shown in FIG. 9 may be applied to subjected each through hole 11 of the lead component mounting portion to the surface treatment.

In the surface treatment by the electrolytic nickel-gold plating means, as shown in FIG. 3, “soldering strength of the surface mounting component”, “surface smoothness”, and “solder rising property in through hole after two reflows on the front and back surfaces” are satisfactory. The soldering strength of the surface mounting component 30 can further be enhanced as compared with the first embodiment, but the electrode for the plating (lead-out wire for the plating) has to be disposed in each through hole 11 of the lead component mounting portion. Therefore, a post-treatment such as electrode cutting after the plating is also required.

As described above in detail, according to the embodiments of the present invention, a highly reliable electronic apparatus can be realized in which solder rising is improved in a case where the lead wires of the electronic component provided with the lead wires are inserted and soldered in the through holes and which is capable of sufficiently bearing the external stresses such as the vibration and shock.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general invention concept as defined by the appended claims and their equivalents.

1. A printed wiring board comprising:
a pad on which a surface mounting component is mounted; and
a through hole into which a lead wire of an electronic component provided with the lead wire is inserted, wherein
a surface treatment is performed to apply nickel-gold plating to the through hole to coat the pad with a water-soluble preflux.

2. The printed wiring board according to claim 1, wherein a surface treatment is performed by using the water-soluble preflux at both sufarface of the circuit substrate, in which the surface mounting component is mounted on both surfaces thereof and an electronic component provided with a lead wire using the through hole is mounted at least one surface thereof.

3. The printed wiring board according to claim 1, wherein the nickel-gold plating is electrolytic nickel-gold plating or electroless nickel-gold plating.

4. An electronic component mounting method comprising:
plating a through hole disposed in a lead component mounting portion on which an electronic component provided with a lead wire is to be mounted with nickel-gold;
coating a pad disposed on a surface mounting portion on which a surface mounting component is to be mounted with a water-soluble preflux to subject a printed wiring board to a surface treatment;
mounting the surface mounting component on the surface mounting portion of the printed wiring board; and
inserting the lead wire of the electronic component provided with the lead wire into the through hole of the printed wiring board to mount the electronic component provided with the lead wire on the lead component mounting portion after the mounting the surface mounting component, wherein
the surface mounting component and the electronic component provided with the lead wire are mounted on the printed wiring board.

5. The electronic component mounting method according to claim 4, wherein the mounting comprises:
mounting the surface mounting component on one surface of the printed wiring board; and
mounting the surface mounting component on the other surface of the printed wiring board.

6. The electronic component mounting method according to claim 4, wherein the plating comprises:
applying electrolytic nickel-gold plating to a through hole portion connected to a lead-out wire for the plating; and
coating the surface mounting portion with a water-soluble preflux.

7. An electronic apparatus comprising:
a substrate comprising a through hole into which a lead wire of an electronic component disposed on a mounting portion of the electronic component to which an external stress is applied is to be inserted and soldered and which is plated with nickel-gold; and
an electronic component whose lead wire is inserted and soldered in the through hole disposed in the substrate and which is mounted on the substrate.

8. The electronic apparatus according to claim 7, when a surface mounting portion of the substrate on which a surface mounting component is to be mounted is subjected to a surface treatment by a water-soluble preflux, and the surface mounting component is mounted on the surface mounting portion.

9. The electronic apparatus according to claim 8, wherein the surface mounting components are disposed on the both surfaces of the substrate.
